(19) United States
(12) Patent Application Publication
(10) Pub. No.: US 2004/0219795 A1
(43) Pub. Date: Nov. 4, 2004

(54) Method to improve breakdown voltage by H2 plasma treat

(75) Inventors: Lih-Ping Li, Hsinchu (TW); Tien-I Bao, Hsin-Chu (TW); Syun-Ming Jang, Hsin-Chu (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Co.

(21) Appl. No.: 10/427,360

(22) Filed: May 1, 2003

(51) Int. Cl. H01L 21/302; H01L 21/461

(52) U.S. Cl. 438/709

(57) ABSTRACT

A new method is provided for the improvement of breakdown performance of a layer of dielectric and the removal of a layer of copper oxide (CuO) from copper interconnects. The formed layer of dielectric, thereby including a formed layer of CuO or Cu₂O is, using the invention, exposed to a H₂ plasma treatment. The H₂ plasma treatment reduces the dielectric constant of the exposed and surrounding layer of low-k dielectric while at the same time removing the layer of CuO.

### BACKGROUND OF THE INVENTION

(1) Field of the Invention

The invention relates to the fabrication of integrated circuit devices, and more particularly, to a method to prevent plasma damage to a dielectric as a result of copper oxide removal.

(2) Description of the Prior Art

Performance improvements of Integrated Circuits are typically achieved by device miniaturization, which results in increasing the packaging density of the created Integrated Circuits. Methods and materials that are applied for interconnecting Integrated Circuits are therefore becoming an increasingly more important part of creating packaged semiconductor devices.

The selection of insulation materials and the selection of the materials that are used for the creation of interconnect metal continue to be explored as part of a continuing effort to improve device performance. In this respect for instance methods and materials are explored that allow for the creation of low-k dielectric interfaces between adjacent layers of interconnect metal. In addition, the materials that are used for the creation of the interconnect metal, such as interconnect vias and interconnect traces, continues to present a challenge.

For the creation of conductive interconnects, copper has increasingly gained acceptance and is increasingly being used for this purpose. Copper is known to have a relatively low cost and low resistivity, copper however has a large diffusion coefficient into silicon dioxide and silicon. Copper from an interconnect may diffuse into a surrounding silicon dioxide layer, causing the dielectric to become conductive and decreasing the dielectric strength of the silicon dioxide layer. Copper interconnects are therefore conventionally encapsulated by at least one layer of diffusion barrier material that prevents diffusion of the copper into the surrounding dielectric such as a layer of silicon dioxide. In selecting a material for the creation of a barrier layer, consideration must be given to selecting materials that do not have a relatively high dielectric constant, since such a material causes an undesirable increase in the capacitance between the interconnect metal and the underlying substrate.

Copper is also known to have low adhesive strength to various insulating layers while it is difficult to pattern by masking and etching a blanket layer of copper in order to create intricate structural semiconductor device and circuit elements.

To create conductive interconnect lines and vias, the damascene or dual damascene process is frequently used. For the creation of Very and Ultra Large Scale Integrated devices using the dual damascene process, a layer of insulating or dielectric material is patterned and developed, creating several thousand openings there-through for conductive interconnect traces and vias. These openings are simultaneously filled with a metal, conventionally aluminum with more recent developments using copper. The in this manner created metal interconnects serve to interconnect active and/or passive elements of the Integrated Circuit.

Damascene is an interconnection fabrication process in which grooves are formed in an insulating layer and filled with metal to form the conductive lines. Dual damascene is a multi-level interconnection process in which, in-addition to forming the grooves of single damascene, conductive via openings also are formed.

The invention concentrates on using copper as a metal interconnect medium, a single or dual damascene pattern of copper is first created and annealed. Line-to-line breakdown voltage must be maintained at a relatively high level. For this reason and in view that a copper surface that is exposed to the environment readily oxidizes, forming a layer of CuO or Cu₂O over the exposed surface, the formed layer of CuO or Cu₂O must be removed prior to further processing of the copper interconnect. Conventionally, the layer of CuO or Cu₂O is removed using a NH₃ plasma treatment. Such a plasma treatment, combined with the use of low-k dielectric for the formation of copper interconnect in or over the surface thereof, typically results in damage to the surrounding low-k dielectric. The invention provides a method whereby the layer of CuO or CU₂O is removed without damaging the surrounding low-k dielectric.

U.S. Pat. No. 6,372,301 B1 (Narasimhan et al.) shows a H₂ plasma treatment of a low-k via opening. This invention provides for improving adhesion of diffusion layers on fluorinated silicon dioxide and essentially plasma treats sidewalls of openings created through a layer of low-k dielectric. The instant invention provides for hydrogen based plasma treatment of a created copper interconnect.

U.S. Pat. No. 6,350,687 B1 (Avanzino et al.) shows a H₂ plasma treatment of a copper interconnect to form and remove a passivation layer before forming a capping layer. This invention does not provide for a hydrogen based plasma treatment and does therefore not provide the advantages of applying a hydrogen based plasma treatment as highlighted below. A passivation layer (40) is formed and is, at a later time in the process of the invention, removed by heat-up, by H₂ plasma treatment or by sputter etching.

U.S. Pat. No. 6,303,505 (Ngo et al.) shows a H₂ plasma treatment on a copper interconnect to reduce the oxides thereon, see cols. 5 and 6. This invention forms a thin layer of copper silicide over a copper interconnect, thereby enhancing adhesion of a thereover created capping layer.

U.S. Pat. No. 6,225,210 B1 (Ngo et al.) shows a H₂ plasma treatment on a copper interconnect and low-k layer of dielectric, see cols. 5 and 6. U.S. Pat. No. 6,225,210 B1 (Ngo et al.) makes the surface of exposed copper more rough and in this manner improves adhesion of an overlying capping layer to the surface thereof. The increased roughness of the exposed copper interconnect is achieved by depositing the capping layer under high-density plasma conditions at an elevated temperature.

U.S. Pat. No. 6,153,523 (Van Ngo et al.) and U.S. Pat. No. 6,165,894 (Pramanick, et al.) show a NH₃ plasma treatment of a copper interconnect and dielectric layers. U.S. Pat. No. 6,153,523 shows an ammonium plasma for the removal of a layer of CuO or Cu₂O and does therefore not provide the advantages of applying a hydrogen-based plasma as highlighted below.

U.S. Pat. No. 6,165,894 (Pramanick et al.) shows an ammonium plasma for the removal of a layer of CuO or Cu₂O and does therefore not provide the advantages of applying a hydrogen based plasma as highlighted below.

### SUMMARY OF THE INVENTION

A first principal objective of the invention is to improve by increasing the breakdown voltage of a layer of dielectric in or over the surface of which a copper interconnect is to be created.

A second principal objective of the invention is to remove a layer of copper oxide from the surface of a copper interconnect without thereby damaging the surface of a surrounding low-k dielectric.

Another objective of the invention is to create a pattern of copper interconnects having high breakdown voltage performance characteristics by improving the breakdown voltage of the low-k dielectric in or over which a copper interconnect is created.

Yet another objective of the invention is to create a pattern of copper interconnects of high reliability.

Yet another objective of the invention is to reduce the dielectric constant of the low-k dielectric in or over which a copper interconnect is created.

A new method is provided for the improvement of breakdown performance of a layer of dielectric and the simultaneous removal of a layer of copper oxide (CuO) from copper interconnects. The formed layer of dielectric, thereby including a formed layer of CuO or Cu₂O is, using the invention, exposed to a H₂ plasma treatment. The H₂ plasma treatment reduces the dielectric constant of the exposed and surrounding layer of low-k dielectric while at the same time removing the layer of CuO.

### BRIEF DESCRIPTION OF THE DRAWINGS

FIG. 1 is a cross section of a conventional formation of copper interconnects.

FIG. 2 shows a cross section of a dual damascene structure and the there-with created elements.

FIG. 3 shows a cross section of the hydrogen-based treatment of the exposed surface of the created dual damascene structure of FIG. 2.

FIG. 4 shows a cross section after an etch stop layer has been deposited, enabling the dual damascene structure for additional processing of overlying interconnect metal.

### DESCRIPTION OF THE PREFERRED EMBODIMENTS

Conventional creation of copper interconnects is first highlighted using FIGS. 1. Specifically referring to the cross section that is shown in FIG. 1, therein are highlighted a semiconductor substrate 10 over which a layer 12 of etch stop material has been deposited. A layer (not shown) of pad oxide may been created between the surface of substrate 10 and the layer 12 of etch stop material for stress relieve. Layer 12 is a layer of conventional etch stop material, layer 16 shown in cross section in FIG. 1 represents the combination of an (optional) barrier layer over which an (optional) layer of copper seed is deposited. The openings created in layer 14 of low-k dielectric, which are presented are being representative of single or dual damascene structures or may be created having sloping sidewalls, are filled with layer 20 of copper, applying conventional methods of metal deposition such as ECP. After the openings have been filled with layers 20 of copper, a thermal anneal is typically applied to the created structure. Excess copper (not shown) that has accumulated over the surface of layer 14 of low-k dielectric is removed, applying well known methods of chemical Mechanical Polishing (CMP) or surface etch.

The cross section of FIG. 1 shows two copper interconnects created in a layer of dielectric created by applying the above highlighted steps. In FIG. 1 the layer 18, of etch stop material, has been deposited over the surface of the created copper interconnects 20, serving as an etch stop for continued, Back-End-Of-Line (BEOF) metallization.

Copper is well known to readily oxidize when exposed to an oxygen-containing medium such as the atmosphere. From this it follows that the exposed surface of copper interconnects 20 is typically covered with a thereover formed layer of CuO. For a number of reasons of device performance, such as (adjacent) line-to-line leakage currents, contact resistant and line-to-line breakdown voltage, the layer of CuO or CU₂O must be removed just prior to further processing of the copper interconnects. Conventionally, a NH3 based plasma treatment is used for this removal of the layer of CuO. The NH₃ plasma treatment however tends to damage the low-k dielectric in or over which the copper interconnects have been created. This plasma treatment must, in view of the objective of the plasma treatment of removing CuO from the surface of copper interconnects, be performed just prior to the deposition of the second layer 18 of etch stop material.

The invention is not dependent on the type of structure that is used to create a copper interconnect, such as a single or dual damascene structure, nor is the invention dependent on the use or lack thereof of layers of barrier material with or without layers of seed metal, nor is the invention dependent on the level of metal that is used for the copper interconnect such as first level metal and any additional overlying layers of metal, nor is the invention dependent on the type of the device in which a copper interconnect is created such as a logic device or a storage device or an Integrated Circuit package in which copper based interconnects or contact pads are being created.

The invention takes as its basic surface on which the invention operates the surface of a layer of copper and provides for the removal of a layer of CuO or Cu₂O that conventionally forms over the layer of copper as a result of exposure of the copper surface to an oxygen containing substance.

The above disclaimers are made partially to highlight that any copper surface can be treated by the invention. The copper surface may be the surface of a single damascene structure, a dual damascene structure, a contact or a via interconnect.

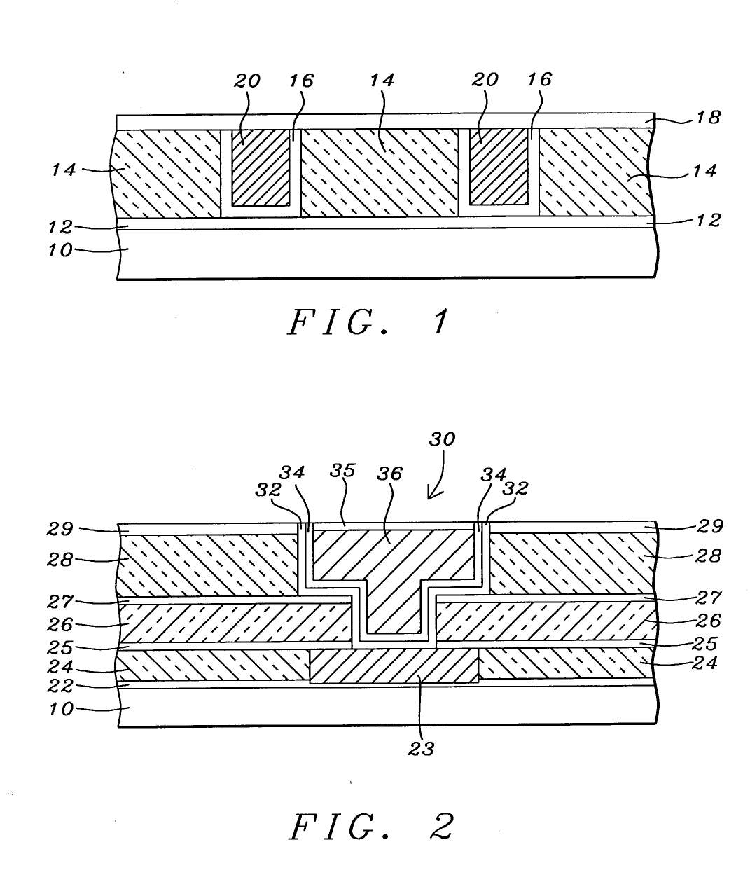

To therefore describe the invention in a somewhat more concrete manner and by way of an example, the surface of a dual damascene structure will be used for the description of the invention, as shown in the cross sections of FIGS. 2-4. A number of the highlighted elements in these FIGS. 2-4 are not germane to the invention but apply to the creation of a dual damascene structure.

Specifically referring to the cross section shown in FIG. 2, therein are highlighted the following elements that collectively form a dual damascene structure:

10, the surface of a semiconductor substrate in or over which semiconductor devices have been created

22, a layer which represents the layer of semiconductor devices that is created in or over the surface of substrate 10

23, the electrical point of first level copper contact which is representative of the points of electrical contact provided in the surface of substrate 10 that provide access to the semiconductor devices created in or over the surface of substrate 10 as represented by layer 22

24, 26 and 28, respectively a first, second and third layers of preferably low-k dielectric

25, 27 and 29, overlying the three layers of dielectric are respectively a first, second and third layer of etch stop material,

30, an opening created through the layers of dielectric and etch stop material, having the cross section of a dual damascene structure, exposing the surface of copper contact point 23

32, a layer of barrier material optionally deposited over inside surfaces of opening 30, deposited to a preferred thickness of between about 50 and 300 Angstrom

34, a layer of copper seed material, deposited over the surface of the barrier layer 32, this deposition is performed to a preferred thickness of between about 300 and 800 Angstrom

36, a layer of copper created over the surface of layer 34 of seed metal, filling the opening 30

typically and not shown in the cross section of FIG. 2, after the structure that is shown in cross section in FIG. 2 has been created, a Rapid Thermal Anneal is applied to the structure that is shown in cross section in FIG. 2, resulting in copper stabilization, and

after the rapid thermal anneal, excess copper (not shown), seed metal and barrier layer material are removed from above the surface of layer 28 of dielectric, applying for this purpose preferably methods of Chemical Mechanical Polishing (CMP) or surface etch, resulting in the structure that is shown in cross section in FIG. 2.

It is clear from the cross section shown in FIG. 2 that the surface of copper interconnect is exposed to the environment, leading to the formation of a layer 35 of CuO or Cu₂O over the surface thereof.

The low-k dielectric that is applied by the invention, such as layers 24, 26 and 28, can be applied using methods of Chemical Mechanical Deposition (CVD) or by methods of spin-on coating. The low-k dielectric can further be organic or inorganic material.

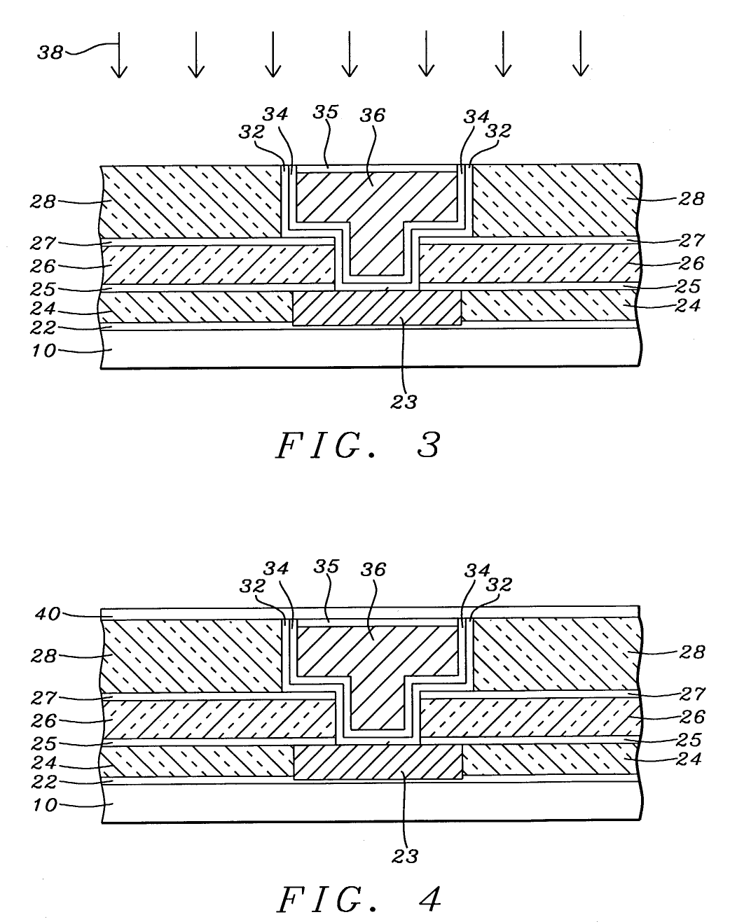

The invention proceeds, FIG. 3, with the application of a H₂ based plasma treatment 38 of the exposited surface of copper interconnect 32 and the surface of the low-k dielectric layer 28. It must be noted in the cross section shown in FIG. 3 that the layer 29, FIG. 2, of etch stop material has been removed from the surface of layer 28 of low-k dielectric in order for increased exposure of this layer 28 to the H₂ based plasma treatment 38.

This H₂ based plasma treatment 38, FIG. 3, has a two-fold objective:

of key and primary importance to the invention, to improve by increasing the breakdown voltage of the layer 28 of low-k dielectric, and

to remove the layer 35 of CuO or Cu₂O from the surface of copper interconnect 36.

As processing conditions for the plasma treatment 38 can be cited applying a plasma density between about 1E10 and 1E12 atoms/cm³, a hydrogen (H₂) flow of between about 50 and 1,800 sccm, at a pressure between about 10 and 350 Torr, a temperature between about 50 and 500 degrees C, a radio frequency power of about 0.005 W/cm², an electrode distance of about 40 mm, a substrate bias between about 0 and 50 Volts, the generated hydrogen plasma being irradiated to the exposure surface for a duration of between about 1 and 60 seconds. The substrate bias may be replaced by applying an energy between about 50 to 220 keV to the plasma. The H₂ flow of the plasma exposure 38 can be created using a precursor gas that is selected from a group of H₂ containing gasses applied with or without an inert gas such as Ne, Kr, Xe, CO, CO₂, He, Ar, N₂ and mixtures thereof.

After the plasma treatment 38, FIG. 3, has been completed, having increased the breakdown voltage of the layer 28 of low-k dielectric and having removed the layer 35 of CuO or Cu₂O from the interconnect 36, a layer 40 of etch stop material or passivation material may be deposited. The structure that is shown in cross section in FIG. 4 is now ready for additional Back-End-Of-Line (BEOL) processing, whereby additional layers of interconnect metal may be created over the surface of the layer 40 of etch stop material.

By substituting a conventional NH₃ based plasma exposure with a H₂ based plasma exposure, the invention has:

1. improved the performance of the low-k dielectric in or over which the copper interconnect has been created by increasing the breakdown voltage of the low-k dielectric, resulting in improved Time Dependent Dielectric Breakdown (TDDB)

2. removed the layer of CuO or Cu₂O from the surface of a created copper interconnect

3. reduced the dielectric constant of the low-k dielectric in or over which the copper interconnect has been created by removing carbon from the low-k dielectric and by thereby making the low-k dielectric more porous, and

4. prevented damage to the surface of the low-k dielectric in or over which the copper interconnect has been created.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method for improving breakdown voltage of a dielectric in or over which a copper interconnect is created, comprising:
providing a substrate, at least one semiconductor device having been created in or over the substrate, at least one point of contact having been provided in or over the substrate to the at least one semiconductor device, a layer of dielectric having been provided over the substrate with at least one copper interconnect there-through providing electrical access to the at least one point of contact; and
exposing the at least one copper interconnect to a H₂ based plasma, thereby increasing the breakdown voltage of the layer of dielectric in addition to removing oxide from the at least one copper interconnect.

2. The method of claim 1, the layer of dielectric comprising a low-k dielectric.

3. The method of claim 1, the at least one copper interconnect comprising a single damascene structure.

4. The method of claim 1, the at least one copper interconnect comprising a dual damascene structure.

5. The method of claim 1, the at least one copper interconnect comprising an interconnect contact.

6. The method of claim 1, the at least one copper interconnect comprising an interconnect via.

7. The method of claim 1, a layer of etch stop material further being deposited over the dielectric, the at least one copper interconnect further being interconnected to overlying interconnect metal.

8. The method of claim 1, a layer of etch stop material additionally having been provided over the substrate prior to providing the layer of dielectric, the least one copper interconnect providing electrical access to the at least one point of contact through the layer of dielectric and the layer of etch stop material.

9. The method of claim 1, the at least one copper interconnect being surrounded by a material selected from the group consisting of copper barrier material and copper seed metal or a combination there-of.

10. A method for improving breakdown voltage of a dielectric in or over which a copper interconnect is created, comprising:
providing a substrate, at least one semiconductor device having been created in or over the substrate, at least one point of contact having been provided in or over the substrate to the at least one semiconductor device, a layer of dielectric having been provided over the substrate with at least one copper interconnect there-through providing electrical access to the at least one point of contact;
exposing the at least one copper interconnect to a H₂ based plasma treatment, thereby increasing the breakdown voltage of the layer of dielectric in addition to removing oxide from the at least one copper interconnect; and
depositing a first layer of etch stop material over the dielectric.

11. The method of claim 10, the layer of dielectric comprising a low-k dielectric.

12. The method of claim 10, the at least one copper interconnect comprising a single damascene structure.

13. The method of claim 10, the at least one copper interconnect comprising a dual damascene structure.

14. The method of claim 10, the at least one copper interconnect comprising an interconnect contact.

15. The method of claim 10, the at least one copper interconnect comprising an interconnect via.

16. The method of claim 10, the at least one copper interconnect further being interconnected to overlying interconnect metal.

17. The method of claim 10, a second layer of etch stop material additionally having been provided over the substrate prior to providing the layer of dielectric, the at least one copper interconnect providing electrical access to the at least one point of contact through the layer of dielectric and the second layer of etch stop material.

18. The method of claim 10, the at least one copper interconnect being surrounded by a material selected from the group consisting of copper barrier material and copper seed metal or a combination there-of.

19. A method for the creation of a copper interconnect, comprising:
providing a substrate, at least one semiconductor device having been created in or over the substrate, at least one point of contact having been provided in or over the substrate to the at least one semiconductor device, a layer of low-k dielectric having been provided over the substrate with at least one copper interconnect there-through providing electrical access to the at least one point of contact;
exposing the at least one copper interconnect to a H₂ based plasma treatment; and
depositing a first layer of etch stop material over the low-k dielectric.

20. The method of claim 19, the at least one copper interconnect comprising a structure selected from the group consisting of a single damascene structure and a dual damascene structure and an interconnect contact and an interconnect via.

21. The method of claim 19, the at least one copper interconnect further being interconnected to overlying interconnect metal.

22. The method of claim 19, a second layer of etch stop material additionally having been provided over the substrate prior to providing the layer of dielectric, the at least one copper interconnect providing electrical access to the at least one point of contact through the layer of dielectric and the second layer of etch stop material.

23. The method of claim 19, the at least one copper interconnect being surrounded by a material selected from the group consisting of copper barrier material and copper seed metal or a combination there-of.

24. The method of claim 1, the layer of dielectric being applied using methods of Chemical Vapor Deposition.

25. The method of claim 1, the layer of dielectric being applied using methods of spin-on coating.

26. The method of claim 1, the layer of dielectric comprising an organic material.

27. The method of claim 1, the layer of dielectric comprising an inorganic material.

28. The method of claim 10, the layer of dielectric being applied using methods of Chemical Vapor Deposition.

29. The method of claim 10, the layer of dielectric being applied using methods of spin-on coating.

30. The method of claim 10, the layer of dielectric comprising an organic material.

31. The method of claim 10, the layer of dielectric comprising an inorganic material.

32. The method of claim 19, the layer of low-k dielectric being applied using methods of Chemical Vapor Deposition.

33. The method of claim 19, the layer of low-k dielectric being applied using methods of spin-on coating.

34. The method of claim 19, the layer of low-k dielectric comprising an organic material.

35. The method of claim 19, the layer of low-k dielectric comprising an inorganic material.

36. A method for improving performance of a layer of dielectric, comprising:
providing a substrate;
depositing a layer of dielectric over the substrate; and
exposing layer of dielectric to a H₂ based plasma treatment.

37. The method of claim 36, the layer of dielectric comprising a low-k dielectric.

38. The method of claim 36, the layer of dielectric further being provided with at least one copper interconnect there-through.

39. The method of claim 38, the at least one copper interconnect comprising a single damascene structure.

40. The method of claim 38, the at least one copper interconnect comprising a dual damascene structure.

41. The method of claim 38, the at least one copper interconnect comprising an interconnect contact.

42. The method of claim 38, the at least one copper interconnect comprising an interconnect via.

43. The method of claim 38, a layer of etch stop material further being deposited over the dielectric, the at least one copper interconnect further being interconnected to overlying interconnect metal.

44. The method of claim 43, a layer of etch stop material additionally having been provided over the substrate prior to providing the layer of dielectric, the at least one copper interconnect providing electrical access to at least one point of contact over the substrate through the layer of dielectric and the layer of etch stop material.

45. The method of claim 38, the at least one copper interconnect being surrounded by a material selected from the group consisting of copper barrier material and copper seed metal or a combination there-of.

46. The method of claim 36, the layer of dielectric being deposited using methods of Chemical Vapor Deposition.

47. The method of claim 36, the layer of dielectric being deposited using methods of spin-on coating.

48. The method of claim 36, the layer of dielectric comprising an organic material.

49. The method of claim 36, the layer of dielectric comprising an inorganic material.

50. A method for improving performance of a layer of low-k dielectric, comprising:
providing a substrate;
depositing a layer of low-k dielectric over the substrate; and
exposing layer of dielectric to a H₂ based plasma treatment.

51. The method of claim 50, the layer of low-k dielectric further being provided with at least one copper interconnect there-through.

52. The method of claim 51, the at least one copper interconnect comprising a single damascene structure.

53. The method of claim 51, the at least one copper interconnect comprising a dual damascene structure.

54. The method of claim 51, the at least one copper interconnect comprising an interconnect contact.

55. The method of claim 51, the at least one copper interconnect comprising an interconnect via.

56. The method of claim 50, a layer of etch stop material further being deposited over the low-k dielectric, the at least one copper interconnect further being interconnected to overlying interconnect metal.

57. The method of claim 50, a layer of etch stop material additionally having been provided over the substrate prior to providing the layer of low-k dielectric, the at least one copper interconnect providing electrical access to at least one point of contact over the substrate through the layer of dielectric and the layer of etch stop material.

58. The method of claim 51, the at least one copper interconnect being surrounded by a material selected from the group consisting of copper barrier material and copper seed metal or a combination there-of.

59. The method of claim 50, the layer of dielectric being deposited using methods of Chemical Vapor Deposition.

60. The method of claim 50, the layer of dielectric being deposited using methods of spin-on coating.

61. The method of claim 50, the layer of dielectric comprising an organic material.

62. The method of claim 50, the layer of dielectric comprising an inorganic material.

63. The method of claim 1, additionally submitting the copper interconnect to a heat treatment after exposing the at least one copper interconnect to a H₂ based plasma.

64. The method of claim 10, additionally submitting the copper interconnect to a heat treatment after exposing the at least one copper interconnect to a H₂ based plasma.

65. The method of claim 19, additionally submitting the copper interconnect to a heat treatment after exposing the at least one copper interconnect to a H₂ based plasma.

66. The method of claim 10, the layer of dielectric comprising an organic-inorganic hybrid material.

67. The method of claim 19, the layer of dielectric comprising an organic-inorganic hybrid material.

68. The method of claim 36, the layer of dielectric comprising an organic-inorganic hybrid material.

69. The method of claim 50, the layer of dielectric comprising an organic-inorganic hybrid material.
